(19) United States
(12) Patent Application Publication
(10) Pub. No.: US 2025/0380532 A1
(43) Pub. Date: Dec. 11, 2025

(54) LIGHT RECEIVING DEVICE

(71) Applicant: SUMITOMO ELECTRIC INDUSTRIES, LTD., Osaka-shi, Osaka (JP)

(72) Inventors: Ryo SUGAHARA, Osaka-shi (JP); Kazutoshi NATSUME, Osaka-shi (JP)

(73) Assignee: SUMITOMO ELECTRIC INDUSTRIES, LTD., Osaka-shi, Osaka (JP)

(21) Appl. No.: 19/214,163

(22) Filed: May 21, 2025

(30) Foreign Application Priority Data
Jun. 7, 2024 (JP) 2024-092890

(51) Int. Cl. H10F 77/14; H10F 30/225

(52) U.S. Cl. CPC H10F 77/147; H10F 30/225

(57) ABSTRACT

A light receiving device includes a first semiconductor layer having a first conductivity type, a light-absorbing layer stacked over a surface of the first semiconductor layer, a second semiconductor layer stacked on a surface of the light-absorbing layer opposite to the first semiconductor layer and having a second conductivity type, a third semiconductor layer stacked on a surface of the second semiconductor layer opposite to the light-absorbing layer, a fourth semiconductor layer stacked on a surface of the third semiconductor layer opposite to the light-absorbing layer and having the second conductivity type, a first electrode electrically connected to the first semiconductor layer, and a second electrode electrically connected to the fourth semiconductor layer. The second semiconductor layer has an impurity concentration higher than an impurity concentration of the third semiconductor layer.

### CROSS REFERENCE TO RELATED APPLICATIONS

This application claims priority based on Japanese Patent Application No. 2024-092890 filed on Jun. 7, 2024, and the entire contents of the Japanese patent application are incorporated herein by reference.

### TECHNICAL FIELD

The present disclosure relates to a light receiving device.

### BACKGROUND

A light receiving device has a plurality of stacked semiconductor layers (for example, Patent literature: Japanese Unexamined Patent Application Publication No. 2011-55014). The semiconductor layers are depleted by applying voltage.

### SUMMARY

A light receiving device according to the present disclosure includes a first semiconductor layer having a first conductivity type, a light-absorbing layer stacked over a surface of the first semiconductor layer, a second semiconductor layer stacked on a surface of the light-absorbing layer opposite to the first semiconductor layer and having a second conductivity type, a third semiconductor layer stacked on a surface of the second semiconductor layer opposite to the light-absorbing layer, a fourth semiconductor layer stacked on a surface of the third semiconductor layer opposite to the light-absorbing layer and having the second conductivity type, a first electrode electrically connected to the first semiconductor layer, and a second electrode electrically connected to the fourth semiconductor layer. The second semiconductor layer has an impurity concentration higher than an impurity concentration of the third semiconductor layer.

### BRIEF DESCRIPTION OF THE DRAWINGS

FIG. 1 is a plan view showing a light receiving device according to an embodiment.

FIG. 2 is a cross-sectional view showing a light receiving device.

FIG. 3 is a cross-sectional view showing a light receiving device.

FIG. 4 is a cross-sectional view showing a light receiving device according to a comparative example.

FIG. 5 is a diagram showing electric field.

FIG. 6A is a schematic diagram showing an energy level of a window layer.

FIG. 6B is a schematic diagram showing an energy level of a window layer.

### DETAILED DESCRIPTION

A window layer may be provided between a light-absorbing layer and a highly doped contact layer. The window layer has a wider band gap than the light-absorbing layer. By providing the window layer, the capacitance of the light receiving device is reduced and the operating band is widened. However, a large electric field is applied to the window layer. The electric field does not contribute to characteristics of the light receiving device, but increases power consumption. Due to the high electric field, dark current increases. Thus, it is an object of the present disclosure to provide a light receiving device capable of reducing capacitance and electric field.

### DESCRIPTION OF EMBODIMENTS OF PRESENT DISCLOSURE

First, the contents of embodiments of the present disclosure will be listed and explained.
(1) A light receiving device according to one aspect of the present disclosure includes a first semiconductor layer having a first conductivity type, a light-absorbing layer stacked over a surface of the first semiconductor layer, a second semiconductor layer stacked on a surface of the light-absorbing layer opposite to the first semiconductor layer and having a second conductivity type, a third semiconductor layer stacked on a surface of the second semiconductor layer opposite to the light-absorbing layer, a fourth semiconductor layer stacked on a surface of the third semiconductor layer opposite to the light-absorbing layer and having the second conductivity type, a first electrode electrically connected to the first semiconductor layer, and a second electrode electrically connected to the fourth semiconductor layer. The second semiconductor layer has an impurity concentration higher than an impurity concentration of the third semiconductor layer. The capacitance decreases as the third semiconductor layer is depleted. By providing the second semiconductor layer, the depletion of the third semiconductor layer is delayed, and the electric field applied to the third semiconductor layer can be reduced.
(2) In the above (1), the second semiconductor layer may have an impurity concentration of 1×10¹⁶ cm⁻³ to 1×10¹⁸ cm⁻³. The electric field can be reduced without inhibiting the depletion.
(3) In the above (1) or (2), the second semiconductor layer may have a thickness of 50 nm to 400 nm. An impurity can be uniformly added to the second semiconductor layer. The electric field can be reduced.
(4) In any one of the above (1) to (3), the third semiconductor layer may have an impurity concentration of 1×10¹⁶ cm⁻³ or lower. The capacitance can be reduced. By providing the second semiconductor layer having a higher impurity concentration than the third semiconductor layer, the electric field can be reduced.
(5) In any one of the above (1) to (4), the first semiconductor layer may have an n-type conductivity, and the second semiconductor layer and the fourth semiconductor layer each may have a p-type conductivity. The electric field can be reduced.
(6) In any one of the above (1) to (5), the fourth semiconductor layer may have a width smaller than a width of each of the third semiconductor layer, the second semiconductor layer, and the light-absorbing layer. It is possible to relax electric field concentration at the junction interface between the fourth semiconductor layer and the third semiconductor layer and at an end portion of a depletion region.
(7) In any one of the above (1) to (6), the second semiconductor layer may be formed of a same material as the third semiconductor layer. Lattice distortion is less likely to occur.
(8) In any one of the above (1) to (7), the light receiving device may be an avalanche photodiode, and the light receiving device may include a multiplication layer stacked below the light-absorbing layer. The light receiving device is the avalanche photodiode, and a high voltage is applied. The electric field can be reduced and edge breakdown can be prevented.

### Details of Embodiments of Present Disclosure

Specific examples of a light receiving device according to the embodiments of the present disclosure will be described below with reference to the drawings. The present disclosure is not limited to these examples, but is defined by the scope of the claims, and is intended to include all modifications within the meaning and scope equivalent to the scope of the claims.

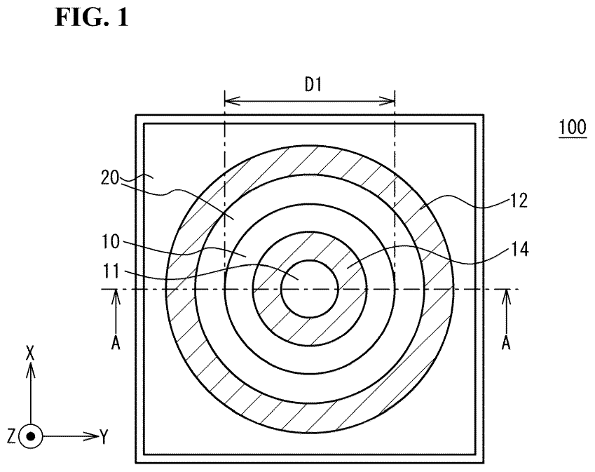

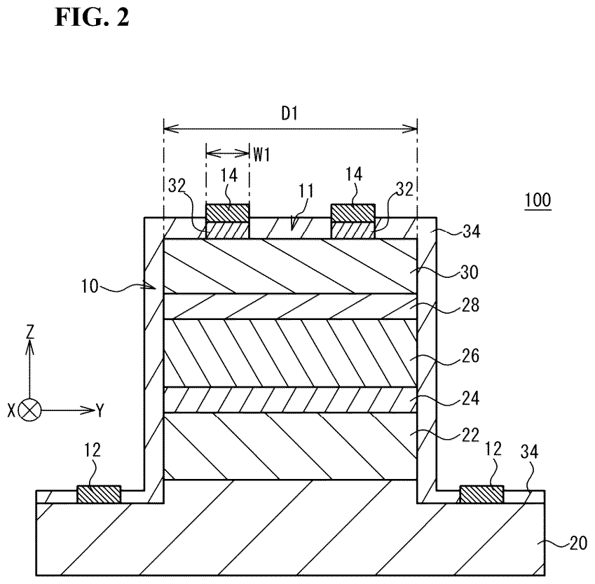

FIG. 1 is a plan view showing a light receiving device 100 according to an embodiment. FIG. 2 is a cross-sectional view showing the light receiving device 100, and shows a cross section taken along line A-A of FIG. 1. The light receiving device 100 is an avalanche photodiode and is used for, for example, light detection and ranging (LiDAR).

As shown in FIG. 1, the light receiving device 100 includes a mesa 10, an electrode 12 (first electrode), an electrode 14 (second electrode), and a buffer layer 20 (first semiconductor layer). A top surface of the buffer layer 20 is parallel to an XY plane. Two sides of the buffer layer 20 are parallel to an X-axis. The other two sides are parallel to a Y-axis. A Z-axis is a thickness direction of the buffer layer 20. The X-axis, the Y-axis, and the Z-axis are orthogonal to each other. In FIG. 1, the electrodes 12 and 14 are hatched.

In a plan view, the mesa 10 is circular. The electrode 12 and the electrode 14 have annular shapes. The electrode 14 is provided in the mesa 10. A portion of the mesa 10 inside the electrode 14 functions as a light receiving region 11. The electrode 12 is provided outside the mesa 10 and surrounds the mesa 10.

As shown in FIG. 2, the light receiving device 100 includes the buffer layer 20, a multiplication layer 22, an adjusting layer 24, a light-absorbing layer 26, an adjusting layer 28 (second semiconductor layer), a window layer 30 (third semiconductor layer), and a contact layer 32 (fourth semiconductor layer), and may include other semiconductor layers. The light receiving device 100 may include a semi-insulating semiconductor substrate (not shown) below the buffer layer 20. The central portion of the buffer layer 20 in the XY plane protrudes in the Z-axis direction from the outer peripheral portion of the buffer layer 20. The multiplication layer 22, the adjusting layer 24, the light-absorbing layer 26, the adjusting layer 28, and the window layer 30 are stacked in this order on the protruding portion of the buffer layer 20. The mesa 10 includes the buffer layer 20, the multiplication layer 22, the adjusting layer 24, the light-absorbing layer 26, the adjusting layer 28, and the window layer 30. A diameter D1 of the mesa 10 is, for example, 30 μm to 300 μm.

The contact layer 32 is provided on a top surface of the window layer 30. The contact layer 32 has an annular shape, and protrudes from the window layer 30 in the Z-axis direction and forms a mesa. A width W1 of the contact layer 32 is smaller than the diameter D1. The top surface of the buffer layer 20 and the side and top surfaces of the mesa 10 are covered with an insulation film 34. The insulation film 34 has an opening at a position spaced apart from the mesa 10. The electrode 12 is provided in the opening. The insulation film 34 has an opening on the mesa 10. The electrode 14 is provided in the opening. The electrode 14 has the same annular shape as the contact layer 32.

The buffer layer 20 is, for example, an n-type (first conductivity type) semiconductor layer, and is formed of n+-type indium phosphorus ((n+)-InP). A thickness of the buffer layer 20 is, for example, 1600 nm. The buffer layer 20 is doped with impurities such as silicon (Si). The impurity concentration is, for example, 1.0×10¹⁸ cm⁻³. The multiplication layer 22 is formed of, for example, undoped indium aluminum arsenide (i-InₓAl₁₋ₓAs (x=0.52)). A thickness of the multiplication layer 22 is, for example, 500 nm. The adjusting layer 24 is formed of, for example, p-type (second conductivity type) indium aluminum arsenide (p-InₓAl₁₋ₓAs (x=0.52)). A thickness of the adjusting layer 24 is, for example, 100 nm. The adjusting layer 24 is doped with impurities such as zinc (Zn). The impurity concentration is, for example, 3.0×10¹⁷ cm⁻³.

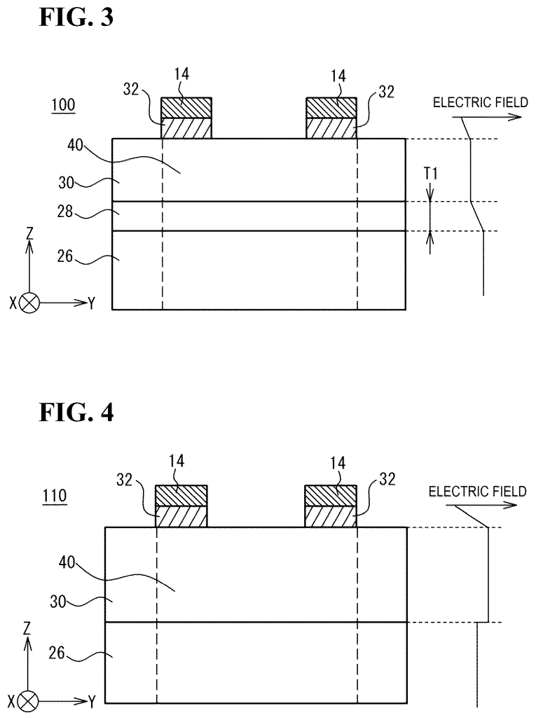

The light-absorbing layer 26 is formed of, for example, undoped indium gallium arsenide (i-InₓGa₁₋ₓAs (x=0.53)). A thickness of the light-absorbing layer 26 is, for example, 1000 nm. The adjusting layer 28 is formed of, for example, (p−)-InₓAl₁₋ₓAs (x=0.52). A thickness of the adjusting layer 28 is denoted as T1 (see FIG. 3). The thickness T1 of the adjusting layer 28 is, for example, 50 nm to 400 nm. The adjusting layer 28 is doped with, for example, Zn. An impurity concentration of the adjusting layer 28 is higher than that of the window layer 30 and lower than that of the contact layer 32, and is, for example, 1×10¹⁶ cm⁻³ to 1×10¹⁸ cm⁻³. A band gap of the adjusting layer 28 is wider than a band gap of the light-absorbing layer 26 and is substantially the same as a band gap of the window layer 30.

The window layer 30 is formed of, for example, i-InₓAl₁₋ₓAs (x=0.52). A thickness of the window layer 30 is, for example, 200 nm. The band gap of the window layer 30 is wider than the band gap of the light-absorbing layer 26. A relative permittivity of the window layer 30 is lower than a relative permittivity of the light-absorbing layer 26. The contact layer 32 is formed of, for example, (p+)-InₓGa₁₋ₓAs (x=0.53). A thickness of the contact layer 32 is, for example, 200 nm. A concentration of Zn doped in the contact layer 32 is, for example, 1×10¹⁹ cm⁻³. Although undoped layers such as the window layer 30 are not intentionally doped with impurities, an impurity of the order of 1×10¹⁵ cm⁻³ may be unintentionally mixed. The semiconductor layers of the light receiving device 100 may be formed of compound semiconductors other than the above.

The insulation film 34 is a passivation film and is formed of an insulator such as silicon nitride (SiN). Each of the electrode 12 and the electrode 14 is formed of metal.

### (Manufacturing Method)

For example, the buffer layer 20 is stacked on one surface of the semi-insulating semiconductor substrate by metal organic chemical vapor deposition (MOCVD) method. The multiplication layer 22, the adjusting layer 24, the light-absorbing layer 26, the adjusting layer 28, the window layer 30, and the contact layer 32 are epitaxially grown in order on one surface of the buffer layer 20. By supplying an impurity together with the source gas, the impurity can be added to the adjusting layer 28 and the like.

Etching is performed to form the contact layer 32 into a ring shape. The mesa 10 is formed by etching a portion of each of the window layer 30, the adjusting layer 28, the light-absorbing layer 26, the adjusting layer 24, the multiplication layer 22, and the buffer layer 20. The insulation film 34 is deposited by plasma enhanced chemical vapor deposition (plasma CVD). Openings are formed in the insulation film 34 by etching in a portion covering the top surface of the mesa 10 and a portion covering the top surface of the buffer layer 20. The electrode 12 and the electrode 14 are formed by vacuum deposition and lift-off. The light receiving device 100 is formed.

The light receiving device 100 can detect light such as infrared light, and detects light having a wavelength of 1.55 μm, for example. When the light receiving device 100 is used, a positive voltage is applied to the electrode 12, and a negative voltage is applied to the electrode 14. A depletion region extends into the mesa 10. Light incident from the light receiving region 11 is absorbed by the light-absorbing layer 26. The light-absorbing layer 26 generates carriers (electron-hole pairs) by absorbing light. Carriers are moved by the electric field applied to the depletion region and are output as photocurrent. The light receiving device 100 is an avalanche photodiode, and the magnitude of the reverse bias voltage is several tens of volts, or about 100 volts, or the like. The adjusting layer 24 functions as an electric field adjusting layer. A high electric field is applied to the multiplication layer 22. The electrons collide with atoms in the multiplication layer 22, and thus more carriers are generated. This improves the sensitivity.

FIG. 3 is a cross-sectional view showing the light receiving device 100, in which the light-absorbing layer 26 to the contact layer 32 are enlarged. The insulation film 34 is omitted. FIG. 3 also shows a schematic view of the electric field distribution corresponding to the stacked structure of the light receiving device 100. By applying the reverse bias voltage, a depletion region 40 is generated in the range of dashed lines. The depletion region 40 extends inward from the outer periphery of the contact layer 32 in the XY plane, and extends to the multiplication layer 22, the light-absorbing layer 26, the adjusting layer 28, and the window layer 30 in the Z-axis direction.

FIG. 4 is a cross-sectional view showing a light receiving device 110 according to a comparative example, and shows the light-absorbing layer 26 to the contact layer 32 as in FIG. 3. The light receiving device 110 does not include the adjusting layer 28. The window layer 30 is stacked on the light-absorbing layer 26. The thickness of the window layer 30 is, for example, 300 nm.

As shown in FIGS. 3 and 4, the window layers 30 are depleted. The capacitance of the light receiving device is reduced. In the example of FIG. 4, a large electric field is applied to the window layer 30 according to the progress of the depletion. The electric field applied to the window layer 30 does not contribute to characteristics of the light receiving device 110. When the light receiving device 110 is driven, an excessive electric field that is not related to the characteristics is generated in the window layer 30, and thus power consumption increases.

As shown in FIG. 3, in the embodiment, the electric field applied to the window layer 30 is smaller than that in the comparative example. The adjusting layer 28 is provided between the light-absorbing layer 26 and the window layer 30. For example, voltage is increased from 0 V to 70 V. The depletion progresses in order from the multiplication layer 22, and the depletion progresses from the adjusting layer 28 to the window layer 30. After the adjusting layer 28 is depleted, the window layer 30 is depleted. That is, the depletion of the window layer 30 is delayed as compared with the comparative example. After the depletion of the window layer 30 starts, an electric field is applied to the window layer 30. At the time when the window layer 30 is depleted, the voltage has risen to about the target value of 70 V. Thus, the electric field applied to the window layer 30 is reduced, and power consumption can be reduced. The progress of the depletion is adjusted according to the thickness and impurity concentration of the adjusting layer 28, and the electric field applied to the window layer 30 can be changed.

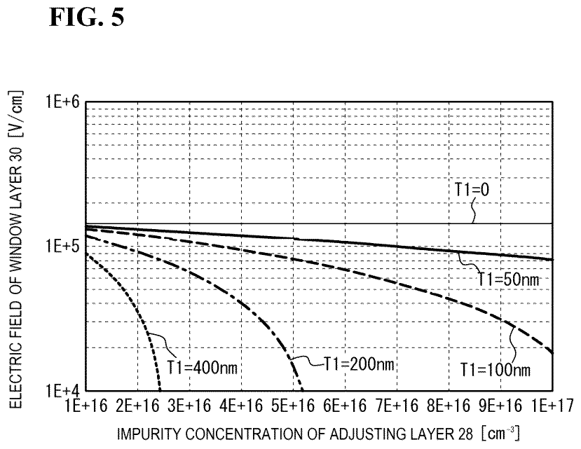

FIG. 5 is a diagram showing electric field. The horizontal axis represents the impurity concentration of the adjusting layer 28. The vertical axis represents the calculation result of the electric field strength in the window layer 30. The vertical axis is a logarithmic scale. A thin solid line represents an example in which the adjusting layer 28 is not provided (T1 is 0). A thick solid line indicates an example in which the thickness T1 of the adjusting layer 28 is 50 nm. A dashed line represents an example in which the thickness T1 is 100 nm. A one dot chain line represents an example in which the thickness T1 is 200 nm. A dotted line represents an example in which the thickness T1 is 400 nm. The semiconductor layers other than the adjusting layer 28 have the above-described configuration.

By providing the adjusting layer 28, the electric field strength can be reduced. When the thickness T1 is constant, the electric field strength decreases as the impurity concentration increases. When the impurity concentration is constant, the electric field strength decreases as the thickness T1 of the adjusting layer 28 increases.

The electric field strength can be reduced by increasing the thickness of the adjusting layer 28 and the impurity concentration. However, when the impurity concentration is higher than 1×10¹⁸ cm⁻³, the depletion is inhibited. When the impurity concentration is lower than 1×10¹⁶ cm⁻³, the electric field strength is not sufficiently reduced. The impurity concentration is set to, for example, 1×10¹⁶ cm⁻³ to 1×10¹⁸ cm⁻³. As the adjusting layer 28 is thicker, it is more difficult to uniformly add the impurity to the adjusting layer 28. When the adjusting layer 28 has the thickness T1 of, for example, 50 nm to 400 nm, the impurity concentration can be made uniform.

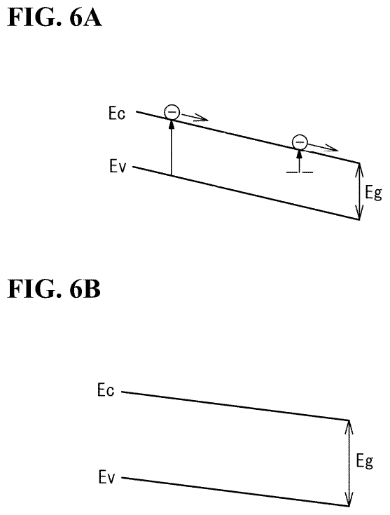

FIGS. 6A and 6B are schematic views showing energy levels of the window layers 30, and show energy levels of the window layers 30 of each of devices according to the embodiment and the comparative example when equal voltages are applied to the light receiving devices. FIG. 6A shows an energy level in the comparative example. FIG. 6B shows an energy level in the embodiment. The energy of the valence band is Ev, and the energy of the conduction band is Ec. An interband energy difference Eg exists in the forbidden band between the valence band and the conduction band.

In the comparative example of FIG. 6A, when the high voltage is applied to the light receiving device, the electric field applied to the window layer 30 is large, and the inclination of the energy band in the window layer 30 is large. Due to the large inclination of the energy band, the substantial interband energy difference Eg in the window layer 30 is reduced. Since the interband energy difference Eg in the window layer 30 is small, electrons are easily excited from the valence band and the donor level to the conduction band. Electrons in the conduction band are accelerated by the large electric field, and dark current is generated. In the embodiment of FIG. 6B, when the high voltage is applied to the light receiving device, the electric field applied to the window layer 30 is small. Thus, the inclination of the energy band in the window layer 30 is smaller than that in the comparative example. Since the inclination of the energy band is small, the substantial interband energy difference Eg in the window layer 30 is not reduced significantly. Since the interband energy difference Eg is large, electrons are not easily excited. Since the electric field is small, carriers are difficult to move, and dark current is reduced.

The contact layer 32 and the window layer 30 are in a heterojunction. In the comparative example, since the high electric field is applied to the window layer 30, the high electric field is also applied to the junction interface. The electric field is likely to concentrate around an interface between an end portion of the mesa-type contact layer 32 and the window layer 30. Edge breakdown may occur. In the embodiment, since the electric field applied to the window layer 30 is reduced, the electric field applied to the junction interface is also reduced. Electric field concentration at or near the end portion of the contact layer 32 is also relaxed. Edge breakdown is unlikely to occur.

As shown in FIGS. 3 and 4, the depletion region 40 extends inward below the ring-shaped contact layer 32. An end portion of the depletion region 40 is located directly under the outer peripheral portion of the contact layer 32. The electric field is likely to concentrate in the end portion of the depletion region 40. In the comparative example of FIG. 4, the high electric field is applied to the window layer 30, and thus electric field concentration is likely to occur in the light-absorbing layer 26 adjacent to the window layer 30. In detail, the electric field may be concentrated in the end portion of the depletion region 40 in the light-absorbing layer 26. Since the light-absorbing layer 26 has a narrower band gap than the window layer 30, edge breakdown is likely to occur when the high electric field is applied. Tunnel current also increases.

As shown in FIG. 3, in the embodiment, the adjusting layer 28 is provided between the light-absorbing layer 26 and the window layer 30. The slightly doped p-type adjusting layer 28 blocks the electric field concentration in the end portion of the depletion region 40 in the light-absorbing layer 26. The electric field concentration in the light-absorbing layer 26 is relaxed, and thus edge breakdown can be prevented. Tunnel current also decreases.

According to the embodiment, as shown in FIG. 2, the n-type buffer layer 20, the light-absorbing layer 26, the p−-type adjusting layer 28, the window layer 30, and the p-type contact layer 32 are stacked. A positive-intrinsic-negative (pin) junction is formed in the mesa 10, and the depletion region 40 is generated. Since the window layer 30 having a wide band gap is provided, the capacitance of the light receiving device 100 is reduced, and the quantum efficiency is also improved. An impurity concentration of the adjusting layer 28 is higher than an impurity concentration of the window layer 30. The depletion of the window layer 30 is delayed, and the electric field applied to the window layer 30 can be reduced as shown in FIG. 5. It is also possible to reduce dark current and power consumption.

The impurity concentration of the adjusting layer 28 is set to 1×10¹⁶ cm⁻³ to 1×10¹⁸ cm⁻³. As shown in FIG. 5, since the impurity concentration is 1×10¹⁶ cm⁻³ or higher, the electric field can be reduced. Since the impurity concentration is 1×10¹⁸ cm⁻³ or lower, the depletion is less likely to be inhibited, and the depletion region 40 extends into the mesa 10. The impurity concentration may be 5×10¹⁶ cm⁻³ or higher, or 1×10¹⁷ cm⁻³ or higher, and may be 5×10¹⁷ cm⁻³ or lower, or 5×10¹⁸ cm⁻³ or lower. The impurity concentration of the adjusting layer 28 is higher than the impurity concentration of the window layer 30 and lower than the impurity concentration of the contact layer 32.

The thickness T1 of the adjusting layer 28 is 50 nm to 400 nm. As shown in FIG. 5, since the thickness T1 is 50 nm or more, the electric field can be reduced. Since the thickness T1 is 400 nm or less, the adjusting layer 28 can be uniformly doped with impurities. The thickness T1 may be 100 nm or more, and may be 200 nm or less, 300 nm or less, or 500 nm or less.

The window layer 30 may be undoped or slightly doped with a p-type impurity. The impurity concentration of the window layer 30 is 1×10¹⁶ cm⁻³ or lower, and may be on the order of 1×10¹⁵ cm⁻³ or lower. The capacitance can be reduced by providing the window layer 30. The electric field can be reduced by providing the adjusting layer 28 having a higher impurity concentration than the window layer 30.

The buffer layer 20 is an n-type semiconductor layer. The contact layer 32 is p-type. The light-absorbing layer 26 is undoped. A pin junction is formed in the mesa 10. The adjusting layer 28 has the same p-type conductivity as the contact layer 32. The electric field applied to the window layer 30 can be reduced. The contact layer 32 and the adjusting layer 28 may be n-type, and the buffer layer 20 may be p-type.

The width W1 of the contact layer 32 is smaller than the width (the diameter D1 of the mesa 10) of each of the window layer 30, the adjusting layer 28, and the light-absorbing layer 26. As shown in FIG. 2, the mesa 10 includes the window layer 30, the adjusting layer 28, and the light-absorbing layer 26. The ring-shaped contact layer 32 is provided on the top surface of the mesa 10. Electric field concentration is less likely to occur at the heterojunction interface between the contact layer 32 and the window layer 30. Edge breakdown can be prevented.

As shown in FIG. 3, the depletion region 40 extends to the same extent as the outer diameter of the contact layer 32. The electric field concentration at the end portion of the depletion region 40 can be relaxed. The electric field is also less likely to concentrate in the end portion of the depletion region 40 extending to the light-absorbing layer 26. Edge breakdown in the light-absorbing layer 26 having a small band gap can be prevented. Tunnel current can be reduced.

For example, the adjusting layer 28 is formed of the same material as the window layer 30, and both layers are formed of, for example, InAlAs. Lattice distortion in the adjusting layer 28 and the window layer 30 is reduced, and the crystallinity is improved. The adjusting layer 28 may be formed of a semiconductor different from the window layer 30, as long as it is formed of a semiconductor lattice-matched to the semiconductor substrate on which the buffer layer 20 is stacked. The multiplication layer 22, the adjusting layer 24, the adjusting layer 28, and the window layer 30 may be formed of InAlAs or other compound semiconductors. For example, any one of InP, indium aluminum arsenic antimony (InAlAsSb), or aluminum arsenic antimony (AlAsSb) may be used.

The light receiving device 100 is an avalanche photodiode and has the multiplication layer 22. A high voltage of several tens of volts or about 100 volts is applied to the light receiving device 100. When the high voltage is applied, the electric field of the window layer 30 can be reduced. Power consumption can be reduced and edge breakdown can be prevented. The light receiving device 100 may be a photodiode other than the avalanche photodiode.

The embodiments may be applied to an array-type light receiving device. In the array-type light receiving device, a plurality of mesas are arranged in a two dimensional grid pattern, for example. One mesa functions as one photodiode. The embodiment is applied to each of the plurality of mesas.

Although the embodiments of the present disclosure have been described in detail, the present disclosure is not limited to the specific embodiments, and various modifications and changes can be made within the scope of the gist of the present disclosure described in the claims.

What is claimed is:

1. A light receiving device comprising:
a first semiconductor layer having a first conductivity type;
a light-absorbing layer stacked over a surface of the first semiconductor layer;
a second semiconductor layer stacked on a surface of the light-absorbing layer opposite to the first semiconductor layer and having a second conductivity type;
a third semiconductor layer stacked on a surface of the second semiconductor layer opposite to the light-absorbing layer;
a fourth semiconductor layer stacked on a surface of the third semiconductor layer opposite to the light-absorbing layer and having the second conductivity type;
a first electrode electrically connected to the first semiconductor layer; and
a second electrode electrically connected to the fourth semiconductor layer,
wherein the second semiconductor layer has an impurity concentration higher than an impurity concentration of the third semiconductor layer.

2. The light receiving device according to claim 1, wherein the second semiconductor layer has an impurity concentration of 1×10¹⁶ cm⁻³ to 1×10¹⁸ cm⁻³.

3. The light receiving device according to claim 1, wherein the second semiconductor layer has a thickness of 50 nm to 400 nm.

4. The light receiving device according to claim 1, wherein the third semiconductor layer has an impurity concentration of 1×10¹⁶ cm⁻³ or lower.

5. The light receiving device according to claim 1,
wherein the first semiconductor layer has an n-type conductivity, and
the second semiconductor layer and the fourth semiconductor layer each have a p-type conductivity.

6. The light receiving device according to claim 1,
wherein the fourth semiconductor layer has a width smaller than a width of each of the third semiconductor layer, the second semiconductor layer, and the light-absorbing layer.

7. The light receiving device according to claim 1,
wherein the second semiconductor layer is formed of a same material as the third semiconductor layer.

8. The light receiving device according to claim 1,
wherein the light receiving device is an avalanche photodiode, and
the light receiving device includes a multiplication layer stacked below the light-absorbing layer.
